(19) United States
(12) Patent Application Publication
(10) Pub. No.: US 2012/0100717 A1
(43) Pub. Date: Apr. 26, 2012

(54) TRENCH LITHOGRAPHY PROCESS

(75) Inventors: Tom Lii, Plano, TX (US); Karen Hildegard Ralston Kirmise, Richardson, TX (US)

(73) Assignee: TEXAS INSTRUMENTS INCORPORATED, Dallas, TX (US)

(21) Appl. No.: 13/280,601

(22) Filed: Oct. 25, 2011

Related U.S. Application Data
(60) Provisional application No. 61/406,634, filed on Oct. 26, 2010.

(51) Int. Cl. H01L 21/768; H01L 21/302

(52) U.S. Cl. 438/675; 438/702; 257/E21.586; 257/E21.214

(57) ABSTRACT

A process of forming an integrated circuit using a dual damascene interconnect process by etching a via hole in an ILD and filling the via hole with a sacrificial via fill material. A trench etch hard mask layer is formed over the ILD. An inorganic hard mask layer is formed over the trench etch hard mask layer. The inorganic hard mask layer is etched to form an etch mask for the trench etch hard mask layer, which is subsequently etched to form an etch mask for the trench etch process. The sacrificial via fill material etches at a comparable rate to the ILD layer. The trench etch hard mask layer is removed and the sacrificial via fill material is removed from the via hole.

This application claims the benefit of U.S. Provisional Application No. 61/406,634, filed Oct. 25, 2010, the entirety of which is herein incorporated by reference.

### FIELD OF THE INVENTION

This invention relates to the field of integrated circuits. More particularly, this invention relates to interconnects in integrated circuits.

### BACKGROUND OF THE INVENTION

An integrated circuit may have interconnects formed by a dual damascene process, in which a via hole is etched in an inter-level dielectric (ILD) layer, followed by etching an interconnect trench over the via hole in the ILD layer, followed by filling the interconnect trench and via hole concurrently with interconnect metal. Forming a trench etch mask for the dual damascene process at linewidths encountered in the 20 nanometer complementary metal oxide semiconductor (CMOS) node has been problematic. Forming the trench etch mask using an organic resin based material, as has been done on earlier CMOS nodes, may result in undesirable loss of pattern integrity due to the higher ratio of the mask thickness to the linewidth, also known as the aspect ratio, on the 20 nanometer node compared to aspect ratios of earlier nodes. Attempts to use more durable material for the trench etch mask have encountered difficulty adequately filling the via hole with the durable material. Processes using a buried metal hard mask have experienced alignment difficulties due to low transmission through the metal hard mask layer as well as increased fabrication cost.

### SUMMARY OF THE INVENTION

The following presents a simplified summary in order to provide a basic understanding of one or more aspects of the invention. This summary is not an extensive overview of the invention, and is neither intended to identify key or critical elements of the invention, nor to delineate the scope thereof. Rather, the primary purpose of the summary is to present some concepts of the invention in a simplified form as a prelude to a more detailed description that is presented later.

In one embodiment, an integrated circuit may be formed with a dual damascene interconnect process in which a via hole is formed through an ILD layer to an underlying layer. The via hole is filled with a sacrificial silicon oxide based or organic via fill material and excess via fill material is removed from a top surface of the ILD layer. A trench etch hard mask layer is formed over the ILD layer and the filled via hole. An inorganic hard mask layer is formed over the trench etch hard mask layer. A photolithographic layer is formed over the inorganic hard mask layer and patterned to expose an interconnect trench area. Material in the inorganic hard mask layer in the interconnect trench area is removed using the patterned photolithographic layer as an etch mask. Material in the trench etch hard mask layer in the interconnect trench area is etched using the etched inorganic hard mask layer as an etch mask. An interconnect trench is etched in the ILD layer using the etched trench etch hard mask layer as an etch mask. The trench etch hard mask layer is then removed. The sacrificial via fill material is then removed from the via hole by a wet etch process.

### DESCRIPTION OF THE VIEWS OF THE DRAWING

FIG. 1A through FIG. 1L are cross sections of an integrated circuit formed according to an embodiment, depicted in successive stages of fabrication.

### DETAILED DESCRIPTION OF EXAMPLE EMBODIMENTS

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide an understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

For the purposes of this Description, the term “plasma containing oxygen” will be understood to refer to a plasma containing any form of oxygen, such as any combination of elemental oxygen, diatomic oxygen, carbon monoxide and carbon dioxide. Similarly, the term “plasma containing nitrogen” will be understood to refer to a plasma containing any form of nitrogen, such as any combination of elemental nitrogen, molecular nitrogen, ammonia and nitrous oxide.

An integrated circuit may be formed with a dual damascene interconnect process in which a via hole is formed through an inter-level dielectric (ILD) layer, for example a low-k dielectric layer with a silicon dioxide cap layer, to an underlying layer, for example an etch stop layer over an underlying interconnect. The via hole is filled with a sacrificial silicon oxide based or organic via fill material, such as a sacrificial light absorbing material (SLAM), for example using a spin on process. Excess via fill material is removed from a top surface of the ILD layer, so that less than 100 nanometers, and possibly none, of the via fill material remains on the ILD layer top surface. A trench etch hard mask layer is formed over the ILD layer and the filled via hole. The trench etch hard mask layer may be, for example, an amorphous carbon layer formed by a chemical vapor deposition (CVD) process or a carbon rich dielectric material formed by plasma enhanced CVD (PECVD). An inorganic dielectric hard mask layer, for example silicon rich nitride or silicon oxy nitride, is formed over the trench etch hard mask layer. A photolithographic layer, for example a bottom anti-reflection coating (BARC) and a photoresist layer, is formed over the inorganic hard mask layer and patterned to expose an interconnect trench area. Material in the inorganic hard mask layer in the interconnect trench area is etched using the patterned photolithographic layer as an etch mask, for example by a reactive ion etch (RIE) process with a fluorine containing plasma. Material in the trench etch hard mask layer in the interconnect trench area is etched using the etched inorganic hard mask layer as an etch mask, for example using an RIE process with a plasma containing oxygen, and/or nitrogen. An interconnect trench is etched in the ILD layer using the etched trench etch hard mask layer as an etch mask. After etching the interconnect trench in the ILD, the remaining trench etch hard mask layer is removed using a plasma containing oxygen. The via fill material is removed from the via hole, for example using a wet etch dissolution process using amine. Material from the etch stop layer at a bottom of the via hole, if present, is removed, after the interconnect trench is etched. Interconnect metal, such as an electrically conductive liner of tantalum nitride and a subsequent electrically conductive fill material of copper, is formed in the interconnect trench and via hole. Excess interconnect metal is removed from the top surface of the ILD, for example by a chemical mechanical polish (CMP) process.

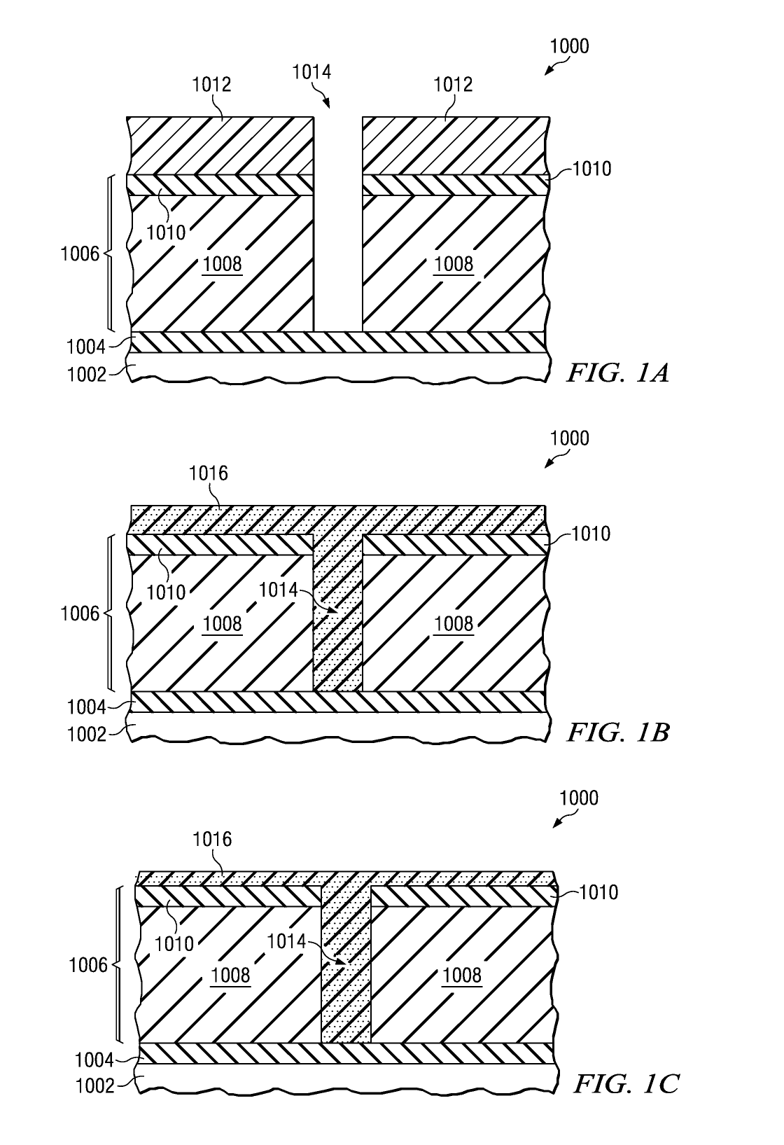

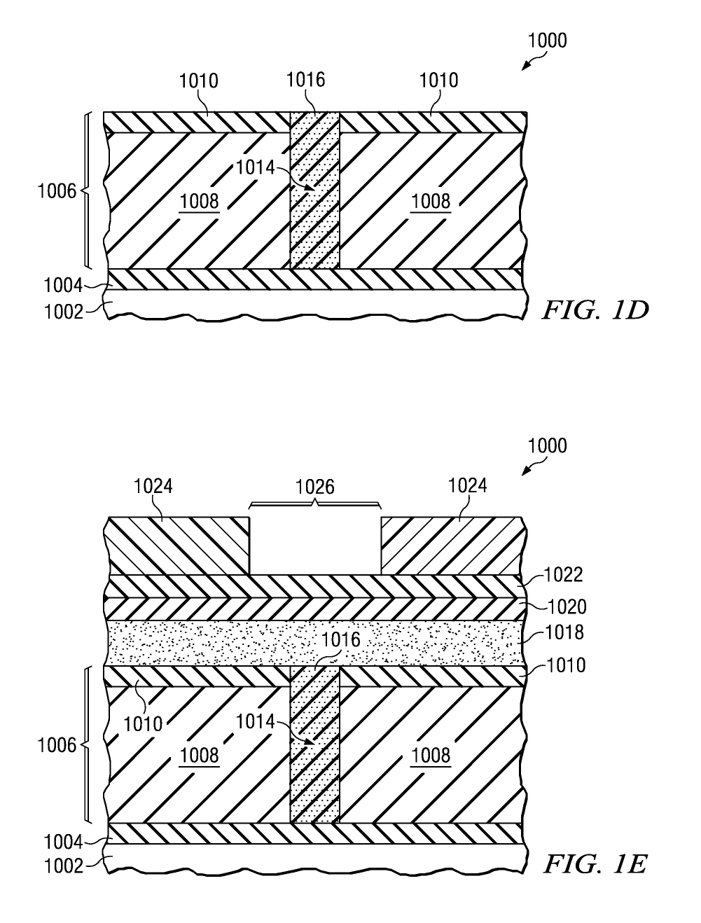

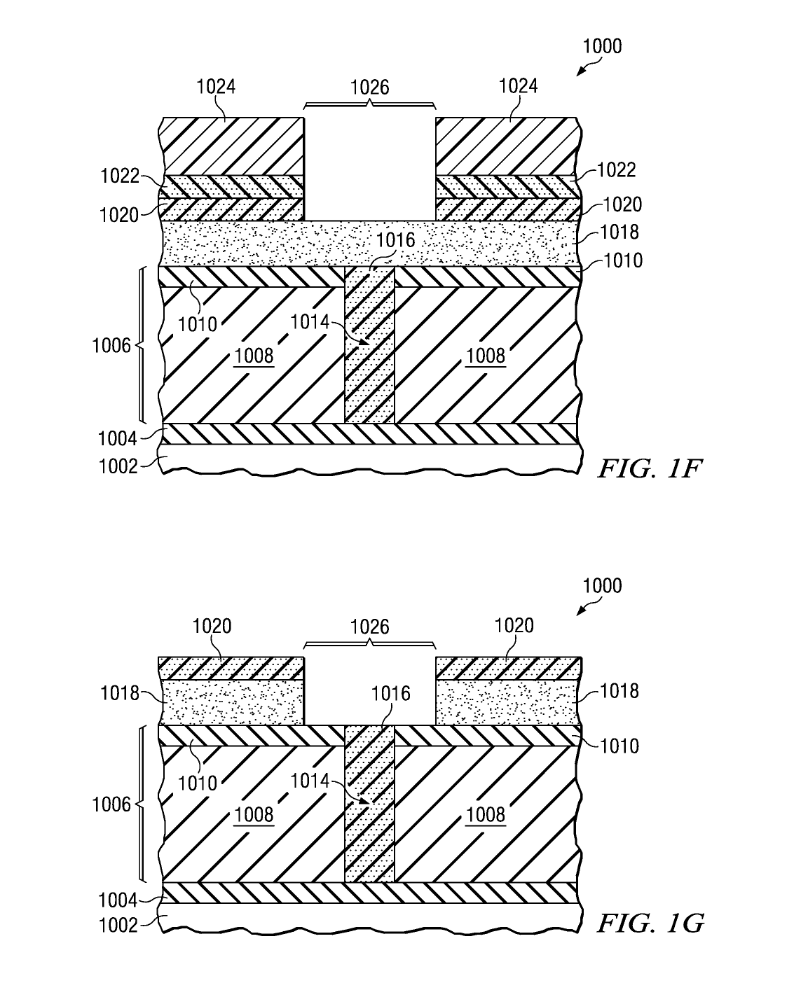

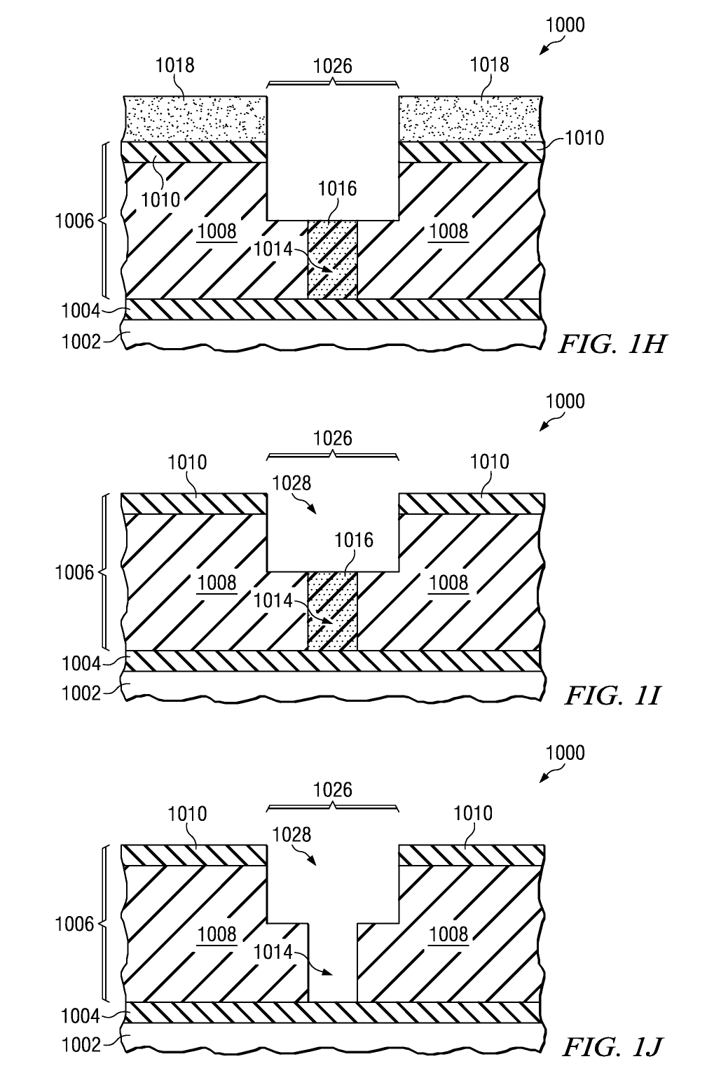

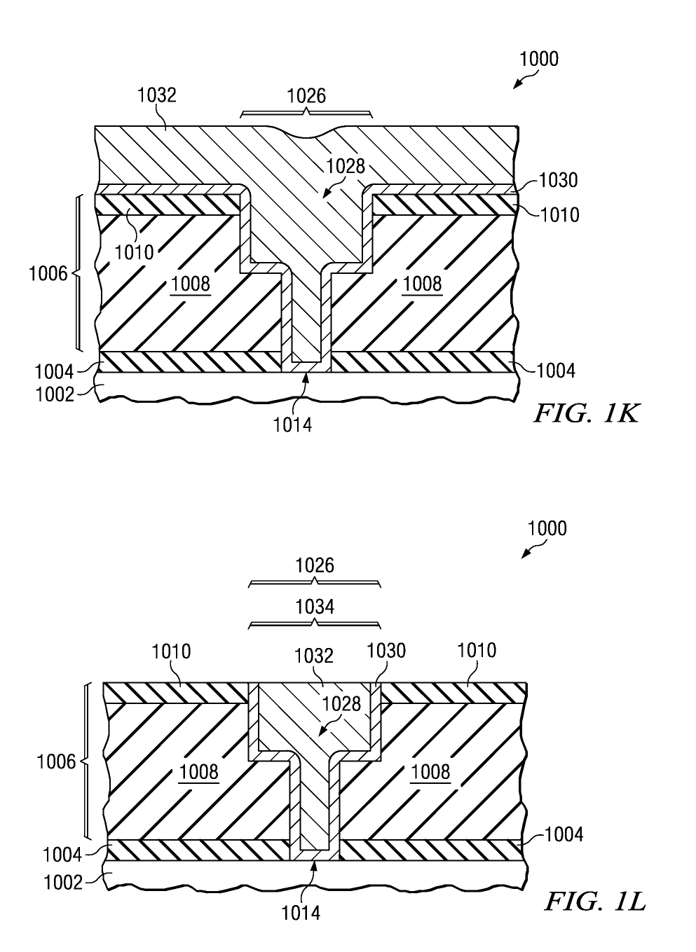

FIG. 1A through FIG. 1L are cross sections of an integrated circuit formed according to an embodiment, depicted in successive stages of fabrication. Referring to FIG. 1A, the integrated circuit 1000 is formed in and on a substrate which may be a semiconductor wafer and possibly one or more dielectric layers. The dielectric layers may include, for example, silicon nitride, silicon dioxide, low-k materials and/or ultra low-k materials. The low-k materials, which have dielectric constants between 2.5 and 3.5, may include organo-silicate glass, carbon-doped silicon oxides and methylsilsesquioxane (MSQ). the ultra low-k materials, which have dielectric constants below 2.5, may include porous silicon dioxide and porous carbon-doped silicon dioxide. An underlying conductive element 1002, such as a metal interconnect, a transistor gate or a silicided active area is formed in the integrated circuit 1000. An optional etch stop layer 1004, for example 5 to 50 nanometers of silicon carbide nitride or silicon carbide oxide, may be formed over the conductive element 1002. An ILD layer 1006 is formed over the conductive element 1002, on the etch stop layer 1004 if present. The ILD layer 1006 includes a main dielectric layer 1008 which may contain for example silicon dioxide, a low-k material, or an ultra low-k material. The main dielectric layer 1008 may be between 50 and 1000 nanometers thick. The ILD layer 1006 may also include a cap layer 1010, for example a layer of silicon dioxide between 5 and 50 nanometers thick formed by thermal decomposition of tetraethyl orthosilicate, also known as tetraethoxysilane or TEOS. The ILD layer 1006 may also include another dielectric layer, not shown, such as a bottom adhesion layer or a trench etch stop layer.

A via etch mask 1012 is formed over the ILD layer 1006 which exposes the ILD layer 1006 in a via area to be etched. The via etch mask 1012 may include one or more layers of dielectric hard mask, such as silicon dioxide, silicon nitride, silicon oxynitride, organic resin, BARC and photoresist. A via etch process is performed which removes material from the ILD layer 1006 in the via area exposed by the via etch mask 1012, to form a via hole 1014 through the ILD layer 1006 to the etch stop layer 1004 if present, as depicted in FIG. 1A, or to the conductive element 1002. A portion, or possibly all, of the etch stop layer 1004 may be removed during formation of the via hole 1014, a condition not depicted in FIG. 1A. Residual dielectric material from the ILD layer 1006 and/or etch residue from the via hole formation process may be present at a bottom of the via hole 1014. The via etch mask 1012 is removed after formation of the via hole 1014 is completed.

Referring to FIG. 1B, a layer of sacrificial via fill material 1016 is formed in the via hole 1014 and over the ILD layer 1006. In one version of the instant embodiment, the sacrificial via fill material 1016 fills the via hole 1014 without forming any voids. The sacrificial via fill material 1016 has an etch rate in a subsequent trench etch process which between 75 percent and 125 percent of an etch rate of the ILD layer 1006. The sacrificial via fill material 1016 may be removed from the via hole 1014 without removal of a significant amount of material from the ILD layer 1006. The sacrificial via fill material 1016 may be a silicon oxide based or organic material, for example a siloxane based polymer as described in Hussein, et al., “A Novel Approach to Dual Damascene Patterning”, Proceedings of the 2002 IITC, pg. 18, 2002, or in Kennedy, et al., “An Anthracene-Organosiloxane Spin on Antireflective Coating for KrF Lithography,” SPIE 28^{th} Annual Microlithography Conference, Feb. 23, 2003. The sacrificial via fill material 1016 may be formed on the integrated circuit 1000, for example, by adding a solvent to the via fill material, dispensing the solvent and via fill material mixture onto the integrated circuit 1000, spinning the integrated circuit 1000 to distribute the solvent and via fill material mixture over the integrated circuit 1000 and into the via hole 1014, followed by removing at least a portion of the solvent, for example by heating the integrated circuit 1000.

Referring to FIG. 1C, excess sacrificial via fill material 1016 is removed, leaving less than 100 nanometers of the sacrificial via fill material 1016 over the ILD layer 1006. The excess sacrificial via fill material 1016 may be removed, for example, using a plasma etch process with a plasma containing fluorine and/or oxygen. In one version of the instant embodiment, all the sacrificial via fill material 1016 over the ILD layer 1006 may be removed, as depicted in FIG. 1D.

Referring to FIG. 1E, a trench etch hard mask layer 1018 is formed over the ILD layer 1006 and via hole 1014 filled with the sacrificial via fill material 1016. The trench etch hard mask layer 1018 is formed from a material which maintains pattern integrity at an aspect ratio required to form an interconnect trench for an integrated circuit fabricated using 20 nanometer node design rules or design rules for smaller features. The trench etch hard mask material is capable of being removed by a process which does not significantly remove material from the ILD layer 1006. In one version of the instant embodiment, the trench etch hard mask layer 1018 may be between 100 and 500 nanometers of amorphous carbon, formed by a CVD process, such as the Advanced Patterning Film™ from Applied Materials, or the Ashable Hardmask™ from Novellus. In another version, the trench etch hard mask layer 1018 may be between 100 and 500 nanometers of carbon rich dielectric material formed by a PECVD process. An inorganic dielectric hard mask layer 1020, for example 10 to 100 nanometers of silicon rich nitride or silicon oxy nitride, is formed over the trench etch hard mask layer 1018. A trench photolithographic layer is formed over the inorganic dielectric hard mask layer 1020. The trench photolithographic layer may include an optional BARC layer 1022 between the inorganic dielectric hard mask layer 1020 and a photoresist layer 1024. The photoresist layer 1024 is patterned to expose an interconnect trench area 1026 over the inorganic dielectric hard mask layer 1020.

Referring to FIG. 1F, a first trench etch process is performed on the integrated circuit 1000 which removes material from the BARC layer 1022 if present and removes material from the inorganic dielectric hard mask layer 1020 in the interconnect trench area 1026, using the patterned photoresist layer 1024 as an etch mask. The first trench etch process may include, for example, an RIE operation with a fluorine containing plasma.

Referring to FIG. 1G, a second trench etch process is performed on the integrated circuit 1000 which removes material from the trench etch hard mask layer 1018 in the interconnect trench area 1026, using the etched inorganic dielectric hard mask layer 1020 as an etch mask. In a version of the instant embodiment in which the trench etch hard mask layer 1018 includes amorphous carbon, the second trench etch process may include, for example, an RIE operation using a plasma containing oxygen, and/or nitrogen. A portion or all of the photoresist layer 1024 and a portion or all of the BARC layer 1022 if present may be removed during the second trench etch process.

Referring to FIG. 1H, a third trench etch process is performed on the integrated circuit 1000 which removes material from the ILD layer 1006 and the sacrificial via fill material 1016 in the trench area 1026, using the etched trench etch hard mask layer 1018 as an etch mask, to form an interconnect trench 1028 in the ILD layer 1006. The third trench etch process may include, for example, an RIE operation with a fluorine containing plasma. In one version of the instant embodiment, an etch rate of the sacrificial via fill material 1016 in the via hole 1014 may be between 75 percent and 125 percent of an etch rate of the ILD layer 1006. A portion or all of the inorganic dielectric hard mask layer 1020 may be removed during the third trench etch process.

Referring to FIG. 1I, the trench etch hard mask layer 1018 of FIG. 1H is removed by a process which does not remove an excessive amount of ILD layer 1006, for example by an plasma etch process using a plasma containing oxygen. An initial width and depth of the interconnect trench 1028 may be adjusted to compensate for material removed from the ILD layer 1006 during removal of the trench etch hard mask layer 1018.

Referring to FIG. 1J, the sacrificial via fill material 1016 of FIG. 1I is removed from the via hole 1014 by a process which does not remove an excessive amount of ILD layer 1006, for example by an amine based wet etch. An initial width of the via hole 1014 may be adjusted to compensate for material removed from the ILD layer 1006 during removal of the sacrificial via fill material 1016.

Referring to FIG. 1K, any material in the etch stop layer 1004 at the bottom of the via hole 1014 is removed, for example by an RIE process, to expose the conductive element 1002. A conformal layer of electrically conductive liner 1030 is formed on sidewalls of the via hole 1014 and interconnect trench 1028 and over the ILD layer 1006. The liner 1030 may be, for example, 1 to 20 nanometers of tantalum nitride. A layer of electrically conductive fill material 1032 is formed on the liner 1030 in the via hole 1014 and interconnect trench 1028 and over the ILD layer 1006. The fill material 1032 may be, for example, at least 50 nanometers of copper. In one version of the instant embodiment, a top surface of the fill material 1032 over the via hole 1014 is higher than the top surface of the ILD layer 1006 adjacent to the via hole 1014.

Referring to FIG. 1L, the fill material 1032 and the liner 1030 are removed from over the top surface of the ILD layer 1006 leaving the fill material 1032 and the liner 1030 in the interconnect trench 1028 and in the via hole 1014, to form a dual damascene interconnect 1034. The fill material 1032 and the liner 1030 may be removed from over the top surface of the ILD layer 1006, for example, by a chemical mechanical polish (CMP) operation and/or an etchback operation.

While various embodiments of the present invention have been described above, it should be understood that they have been presented by way of example only and not limitation. Numerous changes to the disclosed embodiments can be made in accordance with the disclosure herein without departing from the spirit or scope of the invention. Thus, the breadth and scope of the present invention should not be limited by any of the above described embodiments. Rather, the scope of the invention should be defined in accordance with the following claims and their equivalents.

What is claimed is:

1. A process of forming an integrated circuit, comprising the steps:
forming an underlying conductive element in said integrated circuit;
forming an inter-level dielectric (ILD) layer over said conductive element;
forming a via etch mask over said ILD layer which exposes said ILD layer in a via area;
removing material from said ILD layer in said via area to form a via hole through said ILD layer to said etch stop layer;
removing said via etch mask;
forming a layer of sacrificial via fill material in said via hole and over said ILD layer;
removing at least a portion of said sacrificial via fill material over said ILD layer so that less than 100 nanometers of said sacrificial via fill material remains over said ILD layer;
forming a trench etch hard mask layer over said ILD layer and said via hole filled with said sacrificial via fill material;
forming a inorganic dielectric hard mask layer over said trench etch hard mask layer;
forming a trench photolithographic layer over said inorganic dielectric hard mask layer, said trench photolithographic layer including a photoresist layer;
patterning said photoresist layer to expose an interconnect trench area over said inorganic dielectric hard mask layer;
performing a first trench etch process on said integrated circuit so as to remove material from said inorganic dielectric hard mask layer in said interconnect trench area using said photoresist layer as an etch mask;
performing a second trench etch process on said integrated circuit so as to remove material from said trench etch hard mask layer in said interconnect trench area using said inorganic dielectric hard mask layer as an etch mask;
performing a third trench etch process on said integrated circuit so as to remove material from said ILD layer and said sacrificial via fill material in said interconnect trench area using said trench etch hard mask layer as an etch mask to form an interconnect trench in said ILD layer;
removing said trench etch hard mask layer;
removing said sacrificial via fill material from said via hole;
forming a conformal layer of electrically conductive liner on sidewalls of said via hole and said interconnect trench and over said ILD layer;
forming a layer of electrically conductive fill material on said liner in said via hole and said interconnect trench and over said ILD layer, so that a top surface of said fill material over said via hole is higher than a top surface of said ILD layer adjacent to said via hole; and
removing said liner and said fill material from over said top surface of said ILD layer, leaving said liner and said fill material in said interconnect trench and said via hole to form a dual damascene interconnect.

2. The process of claim 1, in which said sacrificial via fill material is siloxane based polymer.

3. The process of claim 1, in which said step of removing at least a portion of said sacrificial via fill material over said ILD layer is performed so that all said sacrificial via fill material over said ILD layer is removed.

4. The process of claim 1, in which said step of removing at least a portion of said sacrificial via fill material over said ILD layer is performed using a plasma containing oxygen and fluorine.

5. The process of claim 1, in which said trench etch hard mask layer is amorphous carbon between 100 and 500 nanometers thick.

6. The process of claim 1, in which said inorganic dielectric hard mask layer is silicon oxy nitride.

7. The process of claim 1, in which said step of performing said second trench etch process to remove material from said trench etch hard mask layer is a reactive ion etch (RIE) process using a plasma containing oxygen.

8. The process of claim 1, in which said step of performing said second trench etch process to remove material from said trench etch hard mask layer is a reactive ion etch (RIE) process using a plasma containing nitrogen.

9. The process of claim 1, in which said step of performing said third trench etch process is performed so that an etch rate of said sacrificial via fill material in said via hole is between 75 percent and 125 percent of an etch rate of said ILD layer.

10. The process of claim 1, in which said step of removing said sacrificial via fill material from said via hole is performed using an amine based wet etch.

11. The process of claim 1, further including the steps:
forming an etch stop layer over said conductive element, performed prior to forming said ILD layer; and
removing material from said etch stop layer so as to expose said underlying conductive element at a bottom of said via hole, performed after removing said sacrificial via fill material from said via hole and prior to forming said conformal layer of liner.

12. The process of claim 1, in which said trench photolithographic layer includes a bottom anti-reflection coating (BARC) layer.

13. A process of forming a dual damascene interconnect, comprising the steps:
providing an ILD layer on an etch stop layer;
forming a via etch mask over said ILD layer which exposes said ILD layer in a via area;
removing material from said ILD layer in said via area to form a via hole through said ILD layer to said etch stop layer;
removing said via etch mask;
forming a layer of sacrificial via fill material in said via hole and over said ILD layer;
removing at least a portion of said sacrificial via fill material over said ILD layer so that less than 100 nanometers of said sacrificial via fill material remains over said ILD layer;
forming a trench etch hard mask layer over said ILD layer and said via hole filled with said sacrificial via fill material;
forming a inorganic dielectric hard mask layer over said trench etch hard mask layer;
forming a trench photolithographic layer over said inorganic dielectric hard mask layer, said trench photolithographic layer including a photoresist layer;
patterning said photoresist layer to expose an interconnect trench area over said inorganic dielectric hard mask layer;
performing a first trench etch process on said integrated circuit so as to remove material from said inorganic dielectric hard mask layer in said interconnect trench area using said photoresist layer as an etch mask;
performing a second trench etch process on said integrated circuit so as to remove material from said trench etch hard mask layer in said interconnect trench area using said inorganic dielectric hard mask layer as an etch mask;
performing a third trench etch process on said integrated circuit so as to remove material from said ILD layer and said sacrificial via fill material in said interconnect trench area using said trench etch hard mask layer as an etch mask to form an interconnect trench in said ILD layer;
removing said trench etch hard mask layer; and
removing said sacrificial via fill material from said via hole.

14. The process of claim 13, in which said sacrificial via fill material is siloxane based polymer.

15. The process of claim 13, in which said step of removing at least a portion of said sacrificial via fill material over said ILD layer is performed so that all said sacrificial via fill material over said ILD layer is removed.

16. The process of claim 13, in which said step of removing at least a portion of said sacrificial via fill material over said ILD layer is performed using a plasma containing oxygen and fluorine.

17. The process of claim 13, in which said trench etch hard mask layer is amorphous carbon between 100 and 500 nanometers thick.

18. The process of claim 13, in which said inorganic dielectric hard mask layer is silicon oxy nitride.

19. The process of claim 13, in which said step of performing said second trench etch process to remove material from said trench etch hard mask layer is a reactive ion etch (RIE) process using a plasma containing oxygen.

20. The process of claim 13, in which said step of performing said second trench etch process to remove material from said trench etch hard mask layer is a reactive ion etch (RIE) process using a plasma containing nitrogen.

21. The process of claim 13, in which said step of performing said third trench etch process is performed so that an etch rate of said sacrificial via fill material in said via hole is between 75 percent and 125 percent of an etch rate of said ILD layer.

22. The process of claim 13, in which said step of removing said sacrificial via fill material from said via hole is performed using an amine based wet etch.

23. The process of claim 13, in which said trench photolithographic layer includes a BARC layer.
